(19) United States
(12) Patent Application Publication
(10) Pub. No.: US 2025/0044695 A1
(43) Pub. Date: Feb. 6, 2025

(54) METHOD FOR USING COMPOSITION COMPRISING ORGANIC ACID COMPOUND, LITHOGRAPHY COMPOSITION COMPRISING ORGANIC ACID COMPOUND, AND METHOD FOR MANUFACTURING RESIST PATTERN

(71) Applicant: Merck Patent GmbH, Darmstadt (DE)

(72) Inventors: Tomotsugu YANO, Kakegawa-shi (JP); Tomohide KATAYAMA, Kakegawa-shi (JP)

(21) Appl. No.: 18/565,554

(22) PCT Filed: May 31, 2022
(86) PCT No.: PCT/EP2022/064670

§ 371 Date: Nov. 30, 2023

(30) Foreign Application Priority Data
Jun. 2, 2021 (JP) 2021-093090

(51) Int. Cl. G03F 7/11; G03F 7/004; G03F 7/038; G03F 7/09; G03F 7/16; G03F 7/40

(52) U.S. Cl. CPC G03F 7/11; G03F 7/0045; G03F 7/0382; G03F 7/091; G03F 7/162; G03F 7/168; G03F 7/40

(57) ABSTRACT

[Problem] A method for reducing standing wave in a lithography process is provided. [Means for Solution]A method for using a composition comprising an organic acid compound (AA) having a certain structure to reduce standing wave in a lithography process. The distance between the antinode (3) and the node (4) in the direction parallel to the substrate (2) is referred to as the internode distance (5). The internode distance (5)/desired pattern width is referred to as the standing wave index. By reducing standing wave that appears in the resist pattern (1), pattern collapse, which is caused due to undesired shape or formation of a notch, is suppressed and stable formation of a finer pattern is facilitated.

### BACKGROUND OF THE INVENTION

### Technical Field

The present invention relates to a method for using a composition comprising an organic acid compound to reduce standing wave in a lithography process. The present invention also relates to a lithography composition comprising an organic acid compound, and methods for manufacturing a resist pattern and a device using the lithography composition.

### Background Art

In recent years, needs for high integration of LSI has been increasing, and refining of patterns is required. In order to respond such needs, lithography processes using KrF excimer laser (248 nm), ArF excimer laser (193 nm), extreme ultraviolet ray (EUV; 13 nm), X-ray of short wavelength, electron beam or the like have been put to practical use. In order to respond to such refining of resist patterns, also for photosensitive resin compositions to be used as a resist during refining processing, those having high resolution are required. Finer patterns can be formed by exposing with light of a short wavelength, but high dimensional accuracy is required.

In the lithography process, a resist pattern is formed by exposing and developing the resist. The phenomenon in which at the time of exposure, the incident light on the resist and the reflected light from the substrate or the air interface interfere with each other to generate standing wave is known. The generation of standing wave reduces the pattern dimensional accuracy. Attempts have been made to form an anti-reflective coating on the top layer and/or bottom layer of the resist to reduce standing wave.

Attempts have been made to increase the exposure latitude by applying a chemically amplified type resist composition comprising a salt consisting of a particular sulfonic acid and an organic amine on an anti-reflective coating to provide a buffering function (for example, Patent Document 1).

### PRIOR ART DOCUMENTS

### Patent Documents

[Patent document 1] JP 2005-17409 A

### BRIEF DESCRIPTION OF THE DRAWING

FIG. 1 is a schematic illustration showing the cross-sectional view of a negative type resist pattern when affected by standing wave.

FIG. 2 is a schematic illustration showing the cross-sectional view of a negative type resist pattern when not affected by standing wave.

### SUMMARY OF THE INVENTION

### Problems to be Solved by the Invention

The present inventors have focused on controlling the movement of acids in a chemical process in which fine processing is performed. For example, even if an anti-reflective coating is formed on a substrate in a lithography process and a resist film is formed thereon and exposed, standing wave sometimes remains, and a further procedure is required. Further, since the bottom anti-reflective coating needs to be removed after the resist pattern is formed, it cannot sometimes be used in the process or another measure is sometimes needed to be taken.

The present inventors considered that there are one or more problems still need improvements. Examples of these include the following: reducing standing wave in the lithography process; reducing standing wave in the resist pattern; suppressing the non-uniformity of resist pattern width; suppressing the pattern collapse in the resist pattern; obtaining a resist pattern of good shape; obtaining a resist film with good sensitivity; obtaining a resist film with good resolution; obtaining a finer pattern; controlling the movement of acid in the chemical process; suppressing the moving speed of acid in the chemical process; increasing the exposure latitude; increasing the depth of focus; increasing the process margin; obtaining a resist pattern which can be cleanly removed; and improving the yield of the lithography process.

### Means for Solving the Problems

The present invention is to provide a method for using a composition comprising an organic acid compound (AA) and a solvent (B), wherein the organic acid compound (AA) is represented by the formula (aa):

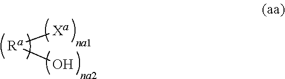

where
R^{a} is C₁₋₄₀ hydrocarbon group, where at least one methylene in the hydrocarbon group can be replaced with carbonyl,
X^{a} is SO₃H or COOH,
na1 is 1 or 2, and
na2 is 0, 1 or 2:
preferably, the composition further comprises a basic compound (AB), where the basic compound (AB) is selected from the group consisting of primary amines, secondary amines and tertiary amines.

The lithography composition according to the present invention comprises an organic acid compound (AA) and a solvent (B), wherein the organic acid compound (AA) is represented by the formula (aa):

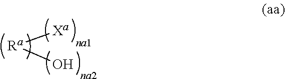

where
R^{a} is C₁₋₄₀ hydrocarbon group, where at least one methylene in the hydrocarbon group can be replaced with carbonyl,
X^{a} is SO₃H or COOH,
na1 is 1 or 2, and
na2 is 0, 1 or 2.

The method for manufacturing a film according to the present invention comprises the following steps:
(1) applying the above-described lithography composition above a substrate; and
(2) forming a film from the lithography composition under reduced pressure and/or heating.

The method for manufacturing a device according to the present invention comprises the above-described method.

### Effects of the Invention

According to the present invention, it is possible to expect one or more of the following effects.

It is possible to reduce standing wave in the lithography process. It is possible to reduce standing wave in the resist pattern. It is possible to suppress the non-uniformity of resist pattern width. It is possible to suppress the pattern collapse in the resist pattern. It is possible to obtain a resist pattern of good shape. It is possible to obtain a resist film with good sensitivity. It is possible to obtain a resist film with good resolution. It is possible to obtain a finer pattern. It is possible to control the movement of acid in the chemical process. It is possible to suppress the moving speed of acid in the chemical process. It is possible to increase the exposure latitude. It is possible to increase the depth of focus. It is possible to increase the process margin. It is possible to obtain a resist pattern which can be cleanly removed. It is possible to improve the yield of the lithography process.

### DETAILED DESCRIPTION OF THE INVENTION

### Mode for Carrying Out the Invention

Embodiments of the present invention are described below in detail.

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “−”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating units, these repeating units copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

### [Method for Using a Composition Comprising an Organic Acid Compound (AA)]

The present invention relates to a method for using a composition comprising an organic acid compound (AA) represented by the formula (aa) (hereinafter sometimes referred to as the composition used in the present invention) to reduce standing wave in a lithography process.

Preferably, the composition used in the present invention is used for being applied above a substrate to form a film. According to the present invention, standing wave can be reduced, so that there is no need to form bottom anti-reflective coating (BARC) in the lower layer of the composition used in the present invention. Therefore, applying the composition used in the present invention without forming any BARC is also a preferred embodiment of the present invention. Further, since the effect of further reduction of standing wave can be exhibited when a BARC is formed, the present invention can be used even when a BARC is formed. The composition for the use method of the present invention is preferably the lithography composition described later.

### Organic Acid Compound (AA)

The organic acid compound (AA) (hereinafter sometimes referred to as the component (AA); the same applies to (B) and thereafter described below) is represented by the formula (aa):

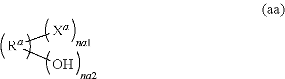

where
R^{a} is C₁₋₄₀, preferably C₁₋₂₀; more preferably C₅₋₁₀, hydrocarbon group. The hydrocarbon group can form a ring. The ring can be an unsaturated ring or a saturated ring. At least one methylene in the hydrocarbon group can be replaced with carbonyl. In a preferred embodiment of the present invention, one methylene in the hydrocarbon group is replaced with carbonyl.
X^{a} is SO₃H or COOH; preferably SO₃H.
na1 is 1 or 2; preferably 1.
na2 is 0, 1 or 2; preferably 0.

Preferably, the organic acid compound (AA) is represented by the formula (aa-1), (aa-2), (aa-3) or (aa-4).

The formula (aa-1) is as follows:

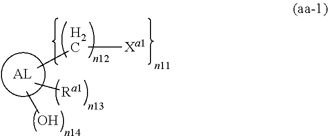

where
AL is a C₅₋₂₀, preferably C₆₋₈, alicyclic ring. At least one methylene in the alicyclic ring can be replaced with carbonyl. In a preferred embodiment of the present invention, one methylene in the alicyclic ring is replaced with carbonyl. A carbon-carbon double bond can be contained in the alicyclic ring, preferably the ring is a saturated alicyclic ring.
X^{a1} is SO₃H or COOH; preferably SO₃H.
R^{a1} is each independently C₁₋₅ alkyl; preferably methyl or ethyl; more preferably methyl.
n11 is 1 or 2; preferably 1.
n12 is 0, 1 or 2; preferably 1.
n13 is 0, 1, or 2; preferably 2.
n14 is 0, 1 or 2; preferably 0.

Exemplified embodiments of the organic acid compound (AA) represented by the formula (aa-1) include 10-canphorsulfonic acid.

The formula (aa-2) is as follows:

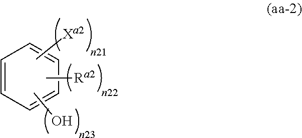

where
X^{a2} is SO₃H or COOH; preferably SO₃H.
R^{a2} is each independently C₁₋₁₅ alkyl; preferably C₁₋₁₂ alkyl; more preferably methyl or dodecyl.
n21 is 1 or 2; preferably 1.
n22 is 0, 1 or 2; preferably 0 or 1; more preferably 1.
n23 is 0, 1 or 2; preferably 0 or 1; more preferably 0.

Exemplified embodiments of the organic acid compound (AA) represented by the formula (aa-2) include p-toluenesulfonic acid, dodecylbenzenesulfonic acid, benzoic acid, 2-hydroxybenzoic acid (salicylic acid), 3-hydroxybenzoic acid and 4-hydroxybenzoic acid.

The formula (aa-3) is as follows:

R^{a3}—X^{a3} (aa-3)
where
X^{a3} is SO₃H or COOH; preferably SO₃H.
R^{a3} is C₁₋₁₀ alkyl, C₁₋₁₀ fluorine-substituted alkyl or C₂₋₁₀ alkenyl; preferably C₁₋₄ alkyl. In the present specification, “fluorine-substituted alkyl” means that a part or all of H in alkyl is substituted with F. In a preferred embodiment, all of H in alkyl are substituted with F. In the present specification, “alkenyl” means a linear or branched hydrocarbon having one carbon-carbon double bond in which one hydrogen is removed from the hydrocarbon.

Exemplified embodiments of the organic acid compound (AA) represented by the formula (aa-3) include methanesulfonic acid, 1-propanesulfonic acid, 1-butanesulfonic acid, trifluoromethanesulfonic acid, heptafluoro-1-propanesulfonic acid, and nonafluoro-1-butanesulfonic acid.

The formula (aa-4) is as follows:

X^{a4}—R^{a4}—X^{a4} (aa-4)
where
X^{a4} is SO₃H or COOH; preferably SO₃H.
R^{a3} is C₁₋₁₀ alkylene or C₂₋₁₀ alkenylene; preferably C₁₋₄ alkylene or C₂₋₄ alkenylene; more preferably methylene or C₂ alkenylene. In the present specification,
“alkenylene” means a divalent hydrocarbon group having one carbon-carbon double bond.

Exemplified embodiments of the organic acid compound (AA) represented by the formula (aa-4) include malonic acid and maleic acid.

More preferably, the organic acid compound (AA) is represented by formula (aa-1) or (aa-2), further preferably represented by formula (aa-1).

Although not to be bound by theory, it is considered that the corporation of the organic acid compound (AA) into the composition used in the present invention can reduce standing wave because it contributes to suppressing the moving speed of the substance generated in the composition during the lithography process (for example, acid generated from the acid generator (D).

For the sake of clarity, in the composition of the present invention comprising the solvent (B), the components contained in the composition can be in an ionic state, a salt or a combination thereof. For example, the organic acid compound (AA) and the basic compound (AB) are dissolved in the solvent (B), and ions and salts can be coexist in the composition.

### Basic Compound (AB)

The composition used for the present invention preferably further comprises a basic compound (AB). The basic compound (AB) is selected from the group consisting of primary amines, secondary amines and tertiary amines. Preferred basic compound (AB) and the content are the same as that indicated for the lithography composition to be described later.

### Solvent (B)

The composition used in the present invention preferably comprises a solvent (B). The preferred solvent (B) and the content are the same as that indicated for the lithography composition to be described later.

### Film-Forming Component (C)

The composition used in the present invention preferably comprises a film-forming component (C). The preferred film-forming component (C) and the content are the same as that indicated for the lithography composition to be described later.

### [Lithography Composition]

The lithography composition according to the present invention comprises an organic acid (AA) represented by the formula (aa) and a solvent (B).

In the present invention, the lithography composition refers to a composition used in a photolithography process, for example, which is used for cleaning and film forming, and in particular, a resist composition, a planarization film forming composition, and a bottom anti-reflective coating forming composition, an top anti-reflective coating forming composition, a rinsing solution, a resist remover, and the like. The lithography composition may or may not be removed after carrying out the process; and preferably, it is removed. The one formed from the lithography composition may or may not remain in the final device; and preferably, it does not remain.

The lithography composition according to the present invention is a lithography film forming composition, more preferably a resist composition. It can be used in either a positive type or a negative type, but preferably, it is a negative type resist composition.

Further, the lithography composition according to the present invention is preferably a chemically amplified type resist composition, more preferably a chemically amplified negative type resist composition, and in this case, in addition to the components (A) and (B), preferably it comprises polymer, an acid generator and a crosslinking agent to be described later.

### Organic Acid Compound (AA)

The organic acid compound (AA) used in the lithography composition of the present invention is as described above, and the preferred embodiments are the same as described above.

The content of the organic acid compound (AA) based on the solvent (B) is preferably 0.001 to 10 mass %; more preferably 0.050 to 1 mass %; further preferably 0.075 to 0.2 mass %.

The content of the organic acid compound (AA) based on the film-forming component (C) is preferably 0.05 to 30 mass %; more preferably 0.1 to 2 mass %; further preferably 0.2 to 1.5 mass %.

### Basic Compound (AB)

The lithography composition according to the present invention preferably further comprise a basic compound (AB). The basic compound (AB) can control the pH of the lithography composition.

The basic compound (AB) is selected from the group consisting of primary amines, secondary amines and tertiary amines; preferably C₂₋₃₂ primary amines, C₃₋₄₈ tertiary amines, C₆₋₃₀ aromatic amines and C₅₋₃₀ heterocyclic amines, and derivatives thereof.

Exemplified embodiments of the basic compound (AB) include triethylamine, triethanolamine, tripropylamine, tributylamine, tri-n-ocylamine, triisopropanolamine, diethylamine, diisopropylamine, di-n-propylamine, di-isobutylamine, di-n-propylamine, diethanolamine, tris[2-(2-methoxyethoxy)ethyl]amine, 1,4-diazabicyclo[2.2.2]octane, piperidine, benzylamine, N,N-dicyclohexylmethylamine. The basic compound (AB) is preferably triethylamine, triethanolamine, tris[2-(2-methoxyethoxy)ethyl]amine, 1,4-diazabicyclo[2.2.2]octane, or benzylamine; more preferably triethanolamine or tris[2-(2-methoxyethoxy)ethyl]amine; and further preferably tris[2-(2-methoxyethoxy)ethyl]amine.

The molecular weight of the basic compound (AB) is preferably 50 to 400; more preferably 100 to 380; further more preferably 200 to 360; and further more preferably 300 to 350.

The basic compound (AB) can be used alone or in combination of two or more of these.

The content of the basic compound (AB) based on the film-forming component (C) is preferably 0 to 40 mass %; more preferably 0 to 10 mass %; further preferably 0.1 to 5 mass %; and further more preferably 0.5 to 2 mass %.

The content of the basic compound (AB) based on the solvent (B) is preferably 0.001 to 10 mass %; more preferably 0.050 to 1 mass %; and further preferably 0.10 to 0.5 mass %. In the composition of the present invention, it is also a preferable embodiment that the composition contains no basic compound (AB) (0.00 mass %).

### Solvent (B)

The solvent (B) used in the present invention is not particularly limited as long as it can dissolve each component to be compounded.

The solvent (B) preferably comprises an organic solvent (B1). It is also a preferable embodiment that the solvent (B) consists only of the organic solvent (B1). The organic solvent (B1) preferably comprises a hydrocarbon solvent, an ether solvent, an ester solvent, an alcohol solvent, a ketone solvent, or any combination of any of these.

Exemplified embodiments of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonane, cyclohexanone, cyclopentanone, methylcyclohexanone, 2,4-pentanedione, acetonylacetone, diacetone alcohol, acetophenone, fenthion, ethyl ether, i-propyl ether, n-butyl ether (di-n-butyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone (GBL), γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, tert-butyl acetoacetate, ethyl propionate, ethyl 3-ethoxypropionate, n-butyl propionate, i-amyl propionate, diethyl oxalate, di-n-butyl oxalate, methyl lactate, ethyl lactate (EL), n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, 3-methoxybutyl acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of two or more of these.

The solvent (B) is preferably PGME, PGMEA, EL, GBL, n-butanol, t-butanol, n-octanol, ethyl 3-ethoxypropionate, 3-methoxybutyl acetate, cyclopentanone, tert-butyl acetoacetate or any combination of any of these, and more preferably PGME, PGMEA or a combination thereof. In preferred embodiment of the present invention, the organic solvent (B1) is PGME, PGMEA or a mixture thereof, and PGME/PGMEA in mass ratio is 0.1 to 10; preferably 0.1 to 1; more preferably 0.2 to 0.5; and further preferably 0.2 to 0.3.

In relation to other layers or films, it is also one embodiment that the solvent (B) substantially contains no water. For example, the amount of water in the total solvent (B) is preferably 0.1 mass % or less, more preferably 0.01 mass % or less, further preferably 0.001 mass % or less. It is also a preferable embodiment that the solvent (B) contains no water (0 mass %).

The content of the solvent (B) based on the lithography composition is preferably 10 to 99.99 mass %; more preferably 75 to 95 mass %; further preferably 80 to 90 mass %.

### Film-Forming Component (C)

The lithography composition according to the present invention preferably comprises a film-forming component (C). In the present invention, the film-forming component (C) refers to a component that constitutes at least a part of the film to be formed. The film to be formed does not have to consist only of the film-forming component (C). For example, the film-forming component (C) and the crosslinking agent (E) described later can combine to form a film. In a preferred embodiment, the film-forming component (C) constitutes most of the film to be formed, for example, 60% or more per volume of the film (more preferably 70% or more; further preferably 80% or more; further more preferably 90% or more).

The film-forming component (C) preferably comprises polymer (C1). A preferred embodiment of the present invention is that the film-forming component (C) is polymer (C1).

Examples of the polymer (C1) include novolak derivatives, phenol derivatives, polystyrene derivatives, polyacrylic acid derivatives, polymaleic acid derivatives, polycarbonate derivatives, polyvinyl alcohol derivatives, polymethacrylic acid derivatives, and copolymers in combination of any of these.

When the lithography composition according to the present invention is a resist composition, it is preferable that the polymer (C1) is polymer generally used in a resist composition whose solubility in an alkaline developer changes due to exposure or the like.

When the lithography composition according to the present invention is a chemically amplified positive type resist composition, the polymer (C1) is preferably one that reacts with an acid to increase its solubility in a developer. Such polymer has, for example, an acid group protected by a protective group, and when an acid is added from outside, the protective group is eliminated and the solubility in a developer is increased.

When the lithography composition according to the present invention is a chemically amplified negative type resist composition, the polymer (C1) is preferably one that crosslinks between the polymers, for example, by a crosslinking agent using an acid generated by exposure as a catalyst to reduce its solubility in a developer.

Such polymer can be freely selected from those generally used in the lithography method. Among such polymer, one having at least one repeating unit represented by the following formulas (c1), (c2) and (c3) is preferable. When the lithography composition according to the present invention is a chemically amplified negative type resist composition, it is preferable that the polymer (C1) has at least a repeating unit represented by the formula (c1).

The repeating unit represented by the formula (c1) is as shown below:

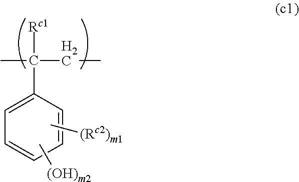

wherein
R^{c1} is H, C₁₋₅ alkyl, C₁₋₅ alkoxy or COOH; preferably H or methyl; more preferably H.
R^{c2} is C₁₋₅ alkyl (where —CH₂— can be replaced with —O—); preferably methyl, ethyl or methoxy; more preferably methyl.
m1 is a number of 0 to 4; preferably 0.
m2 is a number of 1 to 2; preferably 1.
m1+m2≤5.

An exemplified embodiment of the formula (c1) is as shown below:

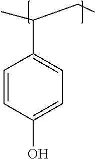

The structural unit represented by the formula (c2) is as shown below:

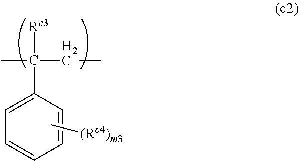

wherein
R^{c3} is H, C₁₋₅ alkyl, C₁₋₅ alkoxy or COOH; preferably H or methyl; more preferably H.
R^{c4} is C₁₋₅ alkyl or C₁₋₅ alkoxy (where —CH₂— in the alkyl or alkoxy can be replaced with —O—); more preferably C₁₋₅ alkoxy (where —CH₂— in the alkoxy can be replaced with —O—), and at this time, m3 is preferably 1. Examples of R^{c4} in this embodiment include methoxy, t-butyloxy and —O—CH(CH₃)—O—CH₂CH₃.
m3 is a number of 0 to 5; preferably 0, 1, 2, 3, 4 or 5; more preferably 0 or 1. It is also a suitable embodiment that m3 is 0.

An exemplified embodiment of the formula (c2) is as shown below:

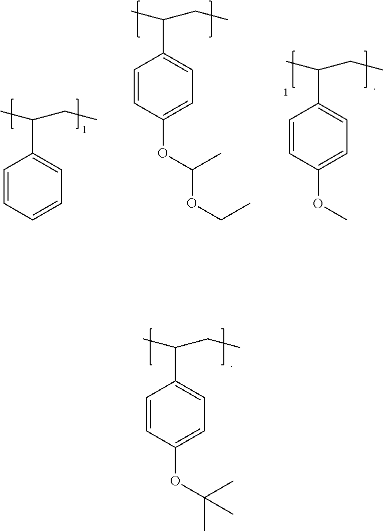

The structural unit represented by the formula (c3) is as shown below:

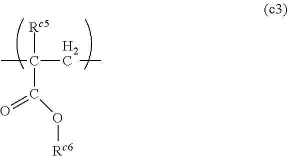

wherein
R^{c5} is H, C₁₋₅ alkyl, C₁₋₅ alkoxy or COOH; more preferably H, methyl, ethyl, methoxy or COOH; further preferably H or methyl; further more preferably H.
R^{c6} is C₁₋₁₅ alkyl or C₁₋₅ alkyl ether, R^{c6} can have a ring structure. R^{c6} is preferably methyl, isopropyl, t-butyl, cyclopentyl, methylcyclopentyl, ethylcyclopentyl, methylcyclohexyl, ethylcyclohexyl, methyl adamantyl or ethyl adamantyl; more preferably t-butyl, ethylcyclopentyl, ethylcyclohexyl or ethyl adamantyl; further preferably t-butyl.

Exemplified embodiments of the formula (c3) are as shown below:

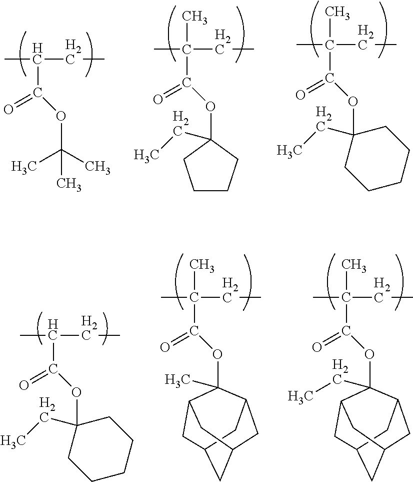

Since these structural units are appropriately compounded according to the purpose, their compounding ratio is not particularly limited, but it is preferable to compound them so that the solubility in an alkaline developer becomes appropriate.

These polymer can also be used in combination of two or more types.

The mass average molecular weight (hereinafter sometimes referred to as Mw) of the polymer (C1) is preferably 500 to 100,000; more preferably 1,000 to 50,000; further preferably 3,000 to 20,000; further more preferably 4,000 to 20,000.

In the present invention, Mw can be measured by the gel permeation chromatography (GPC). In this measurement, it is a preferable example to use a GPC column at 40° C., an eluent tetrahydrofuran at 0.6 mL/min, and mono-dispersed polystyrene as a standard.

The film-forming component (F) can be used alone or in combination of two or more of these.

The content of the film-forming component (C) based on the lithography composition is preferably 2 to 40 mass %; more preferably 2 to 30 mass %; further preferably 5 to 25 mass %; further more preferably 10 to 20 mass %.

Assuming that the ratios of the repeating units represented by the formulas (c1), (c2) and (c3) are respectively n_{c1}, n_{c2} and n_{c3} based on the total number of repeating units in the polymer (C1), the following is one of the preferred embodiments of the present invention.

n_{c1} is 0 to 100%; more preferably 30 to 100%; further preferably 50 to 100%; further more preferably 60 to 100%.

n_{c2} is 0 to 100%; more preferably 0 to 70%; further preferably 0 to 50%; further more preferably 0 to 40%.

n_{c3} is 0 to 50%; more preferably 0 to 40%; further preferably 0 to 30%; further more preferably 0 to 20%. An embodiment that contains no repeating unit represented by the formula (c3) (n_{c3} is 0) is also another preferred embodiment of the present invention.

### Acid Generator (D)

The lithography composition according to the present invention can comprise an acid generator (D). In the present invention, the acid generator refers to a compound itself having an acid generating function. Examples of the acid generator include a photoacid generator (PAG) that generates an acid by exposure and a thermal acid generator (TAG) that generates an acid by heating. When the lithography composition according to the present invention is a chemically amplified type resist composition, it is preferable that PAG is contained.

Examples of PAG include sulfonium salt, iodonium salt, sulfonyl diazomethane and N-sulfonyloxy imide acid generators. Typical PAG are shown below, which can be used alone or in combination of two or more of these.

The sulfonium salt is a salt of an anion containing a carboxylate, a sulfonate or an imide, and a sulfonium cation. Typical examples of the sulfonium cation include triphenyl sulfonium, (4-methylphenyl) diphenyl sulfonium, (4-methoxyphenyl) diphenyl sulfonium, tris(4-methoxyphenyl) sulfonium, (4-tert-butylphenyl) diphenyl sulfonium, (4-tert-butoxyphenyl) diphenyl sulfonium, bis(4-tert-butoxyphenyl) phenyl sulfonium, tris(4-tert-butylphenyl) sulfonium, tris(4-tert-butoxyphenyl) sulfonium, tris(4-methylphenyl) sulfonium, (4-methoxy-3,5-dimethylphenyl) dimethyl sulfonium, (3-tert-butoxyphenyl) diphenyl sulfonium, bis(3-tert-butoxyphenyl) phenyl sulfonium, tris(3-tert-butoxyphenyl) sulfonium, (3,4-di-tert-butoxyphenyl) diphenyl sulfonium, bis(3,4-di-tert-butoxyphenyl) phenyl sulfonium, tris(3,4-di-tert-butoxyphenyl) sulfonium, (4-phenoxyphenyl) diphenyl sulfonium, (4-cyclohexylphenyl) diphenyl sulfonium, bis(p-phenylene) bis(diphenylsulfonium), diphenyl (4-thiophenoxyphenyl) sulfonium, diphenyl (4-thiophenylphenyl) sulfonium, diphenyl (8-thiophenylbiphenyl) sulfonium, (4-tert-butoxycarbonylmethyloxyphenyl) diphenyl sulfonium, tris(4-tert-butoxycarbonylmethyloxyphenyl) sulfonium, (4-tert-butoxyphenyl) bis(4-dimethylaminophenyl) sulfonium, tris(4-dimethylaminophenyl) sulfonium, 2-naphthyl diphenyl sulfonium, dimethyl (2-naphthyl) sulfonium, 4-hydroxyphenyl dimethyl sulfonium, 4-methoxyphenyl dimethyl sulfonium, trimethyl sulfonium, 2-oxocyclohexyl cyclohexylmethyl sulfonium, trinaphthyl sulfonium, and tribenzyl sulfonium. Typical examples of the sulfonate include trifluoromethane sulfonate, nonafluorobutane sulfonate, heptadecafluorooctane sulfonate, 2,2,2-trifluoroethane sulfonate, pentafluorobenzene sulfonate, 4-(trifluoromethyl)benzene sulfonate, 4-fluorobenzene sulfonate, toluene sulfonate, benzene sulfonate, 4-(4-toluene sulfonyloxy)benzene sulfonate, naphthalene sulfonate, camphor sulfonate, octane sulfonate, dodecylbenzene sulfonate, butane sulfonate, and methane sulfonate. Typical examples of the imide include bis(perfluoromethanesulfonyl) imide, bis(perfluoroethanesulfonyl) imide, bis(perfluorobutanesulfonyl) imide, bis(perfluorobutanesulfonyloxy) imide, and bis [perfluoro(2-ethoxyethane)sulfonyl]imide and N,N-hexafluoropropane-1,3-disulfonyl imide. Typical examples of the other anion include 3-oxo-3H-1,2-benzothiazole-2-ide, 1,1-dioxide, tris[(trifluoromethyl)sulfonyl]methanide and tris[(perfluorobutyl)sulfonyl]methanide. Fluorocarbon-containing anions are preferred. Sulfonium salts based on the combination of the above examples are included.

The iodonium salt is a salt of an anion containing a sulfonate and an imide, and an iodonium cation. Typical examples of the iodonium cation include aryliodonium cations, such as diphenyl iodonium, bis(4-tert-butylphenyl) iodonium, bis(4-tert-pentylphenyl) iodonium, 4-tert-butoxyphenylphenyl iodonium and 4-methoxyphenylphenyl iodonium. Typical examples of the sulfonate include trifluoromethane sulfonate, nonafluorobutane sulfonate, heptadecafluorooctane sulfonate, 2,2,2-trifluoroethane sulfonate, pentafluorobenzene sulfonate, 4-(trifluoromethyl)benzene sulfonate, 4-fluorobenzene sulfonate, toluene sulfonate, benzene sulfonate, 4-(4-toluene sulfonyloxy)benzene sulfonate, naphthalene sulfonate, camphor sulfonate, octane sulfonate, dodecylbenzene sulfonate, butane sulfonate, and methane sulfonate. Typical examples of the imide include bis(perfluoromethanesulfonyl) imide, bis(perfluoroethanesulfonyl) imide, bis(perfluorobutanesulfonyl) imide, bis(perfluorobutanesulfonyloxy) imide, bis[perfluoro(2-ethoxyethane)sulfonyl]imide and N,N-hexafluoropropane-1,3-disulfonyl imide. Typical examples of the other anion include 3-oxo-3H-1,2-benzothiazole-2-ide, 1,1-dioxide, tris[(trifluoromethyl)sulfonyl]methanide, and tris[(perfluorobutyl)sulfonyl]methanide. Fluorocarbon-containing anions are preferred. Iodonium salts based on the combination of the above examples are included.

Typical examples of the sulfonyldiazomethane compound include bissulfonyl diazomethane compounds and sulfonylcarbonyl diazomethane compounds, such as bis(ethylsulfonyl) diazomethane, bis(1-methylpropylsulfonyl) diazomethane, bis(2-methylpropylsulfonyl) diazomethane, bis(1,1-dimethylethylsulfonyl) diazomethane, bis(cyclohexylsulfonyl) diazomethane, bis(perfluoroisopropylsulfonyl) diazomethane, bis(phenylsulfonyl) diazomethane, bis(4-methylphenylsulfonyl) diazomethane, bis(2,4-dimethylphenylsulfonyl) diazomethane, bis(2-naphthylsulfonyl) diazomethane, 4-methylphenylsulfonylbenzoyl diazomethane, tert-butylcarbonyl-4-methylphenylsulfonyl diazomethane, 2-naphthylsulfonylbenzoyl diazomethane, 4-methylphenylsulfonyl-2-naphthoyl diazomethane, methylsulfonylbenzoyl diazomethane, and tert-butoxycarbonyl-4-methylphenylsulfonyl diazomethane.

Examples of the N-sulfonyloxy imide photoacid generator include a combination of an imide skeleton and a sulfonic acid. Typical examples of the imide skeleton include succinimide, naphthalenedicarboxylic acid imide, phthalimide, cyclohexyldicarboxylic acid imide, 5-norbornene-2,3-dicarboxylic acid imide, and 7-oxabicyclo[2.2.1]-5-heptene-2,3-dicarboxylic acid imide. Typical examples of the sulfonate include trifluoromethane sulfonate, nonafluorobutane sulfonate, heptadecafluorooctane sulfonate, 2,2,2-trifluoroethane sulfonate, pentafluorobenzene sulfonate, 4-trifluoromethylbenzene sulfonate, 4-fluorobenzene sulfonate, toluene sulfonate, benzene sulfonate, naphthalene sulfonate, camphor sulfonate, octane sulfonate, dodecylbenzene sulfonate, butane sulfonate, and methane sulfonate.

Examples of the benzoin sulfonate photoacid generator include benzointosylate, benzoinmesylate, and benzoinbutane sulfonate.

Examples of the pyrogallol trisulfonate photoacid generator include pyrogallol, phloroglucinol, catechol, resorcinol and hydroquinone, in which all hydroxyl groups are substituted with trifluoromethane sulfonate, nonafluorobutane sulfonate, heptadecafluorooctane sulfonate, 2,2,2-trifluoroethane sulphonate, pentafluorobenzene sulphonate, 4-trifluoromethylbenzene sulphonate, 4-fluorobenzene sulphonate, toluene sulphonate, benzene sulphonate, naphthalene sulphonate, camphor sulphonate, octane sulphonate, dodecylbenzene sulphonate, butane sulfonate or methane sulfonate.

Examples of the nitrobenzyl sulfonate photoacid generator include 2,4-dinitrobenzyl sulfonates, 2-nitrobenzyl sulfonates, and 2,6-dinitrobenzyl sulfonates, and typically sulfonates including trifluoromethane sulfonate, nonafluorobutane sulfonate, heptadecafluorooctane sulphonate, 2,2,2-trifluoroethane sulphonate, pentafluorobenzene sulphonate, 4-trifluoromethylbenzene sulphonate, 4-fluorobenzene sulphonate, toluene sulphonate, benzene sulphonate, naphthalene sulphonate, camphor sulphonate, octane sulfonate, dodecylbenzene sulfonate, butane sulfonate, and methane sulfonate. Further, useful ones are similar nitrobenzyl sulfonate compounds in which the nitro group on the benzyl side is substituted with trifluoromethyl.

Examples of the sulfone photoacid generator include bis(phenylsulfonyl)methane, bis(4-methylphenylsulfonyl)methane, bis(2-naphthylsulfonyl)methane, 2,2-bis(phenylsulfonyl)propane, 2,2-bis(4-methylphenylsulfonyl)propane, 2,2-bis(2-naphthylsulfonyl)propane, 2-methyl-2-(p-toluenesulfonyl)propiophenone, 2-cyclohexylcarbonyl-2-(p-toluenesulfonyl)propane and 2,4-dimethyl-2-(p-toluenesulfonyl)pentan-3-one.

Examples of the photoacid generator in the form of a glyoxime derivative include bis-O-(p-toluenesulfonyl)-α-dimethylglyoxime, bis-O-(p-toluenesulfonyl)-α-diphenylglyoxime, bis-O-(p-toluenesulfonyl)-α-dicyclohexylglyoxime, bis-O-(p-toluenesulfonyl)-2,3-pentandionglyoxime, bis-O-(p-toluenesulfonyl)-2-methyl-3,4-pentanedione-glyoxime, bis-O-(n-butanesulfonyl)-α-dimethylglyoxime, bis-O-(n-butanesulfonyl)-α-diphenylglyoxime, bis-O-(n-butanesulfonyl)-α-dicyclohexylglyoxime, bis-O-(n-butanesulfonyl)-2,3-pentanedioneglioxime, bis-O-(n-butanesulfonyl)-2-methyl-3,4-pentanedione-glyoxyme, bis-O-(methanesulfonyl)-α-dimethylglyoxime, bis-O-(trifluoromethanesulfonyl)-α-dimethylglyoxime, bis-O-(1,1,1-trifluoroethanesulfonyl)-α-dimethylglyoxime, bis-O-(tert-butanesulfonyl)-α-dimethylglyoxime, bis-O-(perfluorooctanesulfonyl)-α-dimethylglyoxime, bis-O-(cyclohexylsulfonyl)-α-dimethylglyoxime, bis-O-(benzenesulfonyl)-α-dimethylglyoxime, bis-O-(p-fluorobenzenesulfonyl)-α-dimethylglyoxime, bis-O-(p-tert-butylbenzenesulfonyl)-α-dimethylglyoxime, bis-O-(xylenesulfonyl)-α-dimethylglyoxime and bis-O-(camphorsulfonyl)-α-dimethylglyoxime.

Among these, preferred PAG is sulfonium salts, iodonium salts and N-sulfonyloxy imides.

The optimal anion for the generated acid varies depending on factors such as the ease of cleavage of acid-labile groups in the polymer, but non-volatile and extremely non-diffusive anions are generally selected. Examples of the suitable anion include anions of benzenesulfonic acid, toluenesulfonic acid, 4-(4-toluenesulfonyloxy)benzenesulfonic acid, pentafluorobenzenesulfonic acid, 2,2,2-trifluoroethanesulfonic acid, nonafluorobutanesulfonic acid, heptadecafluorooctanesulfonic acid, camphorsulfonic acid, disulfonic acid, sulfonylimide and sulfonylmethaneide.

Examples of TAG include metal-free sulfonium salts and iodonium salts, such as triarylsulfonium, dialkylarylsulfonium and diarylalkylsulfonium salts of strong non-nucleophilic acids; alkylaryliodonium, diaryliodonium salts of strong non-nucleophilic acids; and ammonium, alkylammonium, dialkylammonium, trialkylammonium, tetraalkylammonium salts of strong non-nucleophilic acids. Further, covalent thermal acid generators are also considered as useful additives, and examples thereof include 2-nitrobenzyl esters of alkyl or aryl sulfonic acids, and other esters of sulfonic acids that are thermally decomposed to give free sulfonic acids. Examples thereof include diaryliodonium perfluoroalkyl sulfonate, diaryliodonium tris(fluoroalkylsulfonyl) methide, diaryliodonium bis(fluoroalkylsulfonyl) methide, diaryliodonium bis(fluoroalkylsulfonyl) imide and diaryliodonium quaternary ammonium perfluoroalkyl sulfonate. Examples of the labile ester include 2-nitrobenzyl tosylate and 2,4-dinitrobenzyl tosylate, 2,6-dinitrobenzyl tosylate, 4-nitrobenzyl tosylate; benzene sulfonates such as 2-trifluoromethyl-6-nitrobenzyl 4-chlorobenzene sulfonate and 2-trifluoromethyl-6-nitrobenzyl 4-nitrobenzene sulfonate; phenolic sulfonate esters such as phenyl 4-methoxybenzene sulfonate; quaternary ammonium tris(fluoroalkylsulfonyl) methides; quaternary alkylammonium bis(fluoroalkylsulfonyl) imides; and alkylammonium salts of organic acids such as triethylammonium salt of 10-camphorsulfonic acid. Various aromatic (anthracene, naphthalene or benzene derivatives) sulfonic acid amine salts such as those disclosed in U.S. Pat. Nos. 3,474,054, 4,200,729, 4,251,665 and 5,187,019 can also be used as the TAG.

The acid generator (D) can be used alone or in combination of two or more of these.

The content of the acid generator (D) based on the film-forming component (C) is preferably 0.5 to 20 mass %; more preferably 1.0 to 10 mass %; further preferably 2 to 6 mass %; further more preferably 2 to 5 mass %.

### Crosslinking Agent (E)

The lithography composition according to the present invention can comprise a crosslinking agent (E). In the present invention, the crosslinking agent refers to the compound itself having a crosslinking function. The crosslinking agent is not particularly limited as long as it crosslinks the component (C) intramolecularly and/or between the molecules.

Examples of the crosslinking agent include melamine compounds, guanamine compounds, glycoluril compounds or urea compounds substituted by at least one group selected from a methylol group, an alkoxymethyl group and an acyloxymethyl group; epoxy compounds; thioepoxy compounds; isocyanate compounds; azide compounds; and compounds comprising a double bond such as an alkenyl ether group. Further, compounds comprising a hydroxy group can also be used as the crosslinking agent.

Examples of the epoxy compound include tris(2,3-epoxypropyl)isocyanurate, trimethylolmethane triglycidyl ether, trimethylolpropane triglycidyl ether and triethylolethane triglycidyl ether. Examples of the melamine compound include compounds derived by methoxymethylation of 1 to 6 methylol groups of hexamethylolmelamine, hexamethoxymethylmelamine or hexamethylolmelamine, and mixtures thereof; and compounds derived by acyloxymethylation of 1 to 6 methylol groups of hexamethoxyethylmelamine, hexaacyloxymethylmelamine or hexamethylolmelamine, and mixtures thereof. Examples of the guanamine compound include compounds derived by methoxymethylation of 1 to 4 methylol groups of tetramethylolguanamine, tetramethoxymethyl-guanamine or tetramethylolguanamine, and mixtures thereof; and compounds derived by acyloxymethylation of 1 to 4 methylol groups of tetramethoxyethylguanamine, tetraacyloxyguanamine or tetramethylolguanamine, and mixtures thereof. Examples of the glycoluril compound include compounds derived by methoxymethylation of 1 to 4 methylol groups of tetramethylolglycoluril, tetramethoxyglycoluril, tetramethoxymethylglycoluril or tetramethylolglycoluril, and mixtures thereof; and compounds derived by acyloxymethylation of 1 to 4 methylol groups of tetramethylolglycoluril, and mixtures thereof. Examples of the urea compound include compounds derived by methoxymethylation of 1 to 4 of methylol groups of tetramethylolurea, tetramethoxymethylurea or tetramethylolurea, and mixtures thereof; tetramethoxyethylurea, and the like. Examples of the compound containing an alkenyl ether group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, trimethylolpropane trivinyl ether, and the like.

Examples of the crosslinking agent containing a hydroxy group include the following:

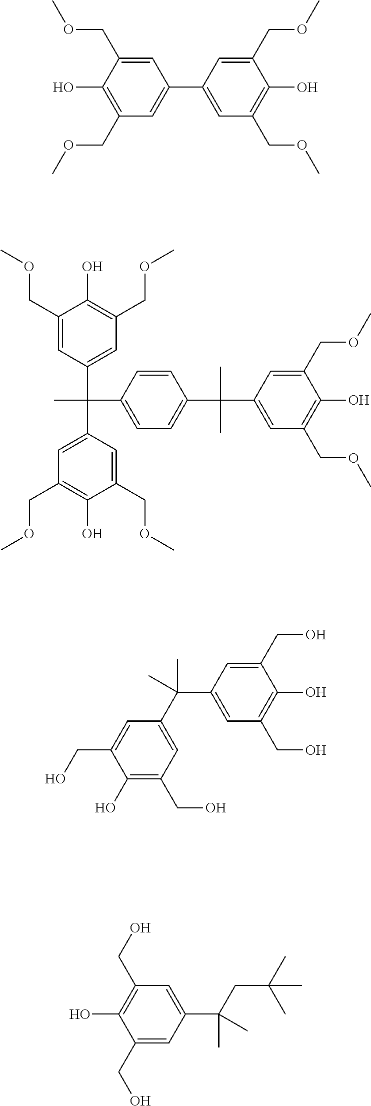

The crosslinking temperature for the film formation is preferably 50 to 230° C.; further preferably 80 to 220° C.; and further more preferably 80 to 190° C.

The crosslinking agent (E) can be used alone or in combination of two or more of these.

The content of the crosslinking agent (E) based on the film-forming component (C) is preferably 3 to 30 mass %; more preferably 5 to 20 mass %; and further more preferably 5 to 12 mass %.

### Surfactant (F)

The lithography composition according to the present invention preferably comprises a surfactant (F). The coatability can be improved by making a surfactant (F) be comprised in the lithography composition according to the present invention. Examples of the surfactant that can be used in the present invention include (I) anionic surfactants, (II) cationic surfactants or (III) nonionic surfactants, and particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether, fluorine-containing surfactants (for example, Fluorad (3M), Megafac (DIC), Surflon (AGC) and organic siloxane surfactants (for example, KF-53, KP341 (Shin-Etsu Chemical)) are included.

The surfactant (F) can be used alone or in combination of two or more of these. The content of the surfactant (F) based on the film-forming component (C) is preferably 0.05 to 0.5 mass %; more preferably 0.09 to 0.2 mass %.

### Additive (G)

The lithography composition according to the present invention can comprise an additive (G) other than the components (A) to (F). The additive (G) preferably comprises a plasticizer, a dye, a contrast enhancer, an acid, a radical generator, a substrate adhesion enhancer, an antifoaming agent, or any combination of any of these. The acid in the additive (G) do not include the organic acid compound represented by formula (aa).

The content of the additive (G) (in the case of a plurality, the sum thereof) based on the composition is preferably 0.1 to 20 mass %; more preferably 0.1 to 10 mass %; and further preferably 1 to 5 mass %. It is also one embodiment of the present invention that the composition according to the present invention contains no additive (G) (0.0 mass %).

The content of the additive (G) (in the case of a plurality, the sum thereof) based on the film-forming component (C) is preferably 0.1 to 10 mass %; more preferably 0.05 to 5 mass %; and further preferably 0.5 to 2.5 mass %.

### [Method for Manufacturing a Film]

The method for manufacturing a film according to the present invention comprises the following steps:
(1) applying the lithography composition according to the present invention above a substrate; and
(2) forming a film from the lithography composition under reduced pressure and/or heating.

Hereinafter, the numbers in parentheses indicate the order of the steps. For example, when the steps (1), (2) and (3) are described, the order of the steps is as described above.

In the present invention, the film is one dried or cured and is, for example, one includes a resist film.

According to the present invention, since the influence of standing wave can be reduced during film formation, BARC is not needed to be formed above the substrate before applying the lithography composition. This is preferable because the step of removing BARC is not needed.

Hereinafter, one embodiment of the manufacturing method according to the present invention is described.

The lithography composition according to the present invention is applied above a substrate (for example, a silicon/silicon dioxide-coated substrate, a silicon nitride substrate, a silicon wafer substrate, a glass substrate, an ITO substrate, and the like) by an appropriate method. Here, in the present invention, the “above” includes the case where a film is formed immediately above a substrate and the case where a film is formed above a substrate via another layer. For example, a planarization film can be formed immediately above a substrate, and the composition according to the present invention can be applied immediately above the planarization film. In a preferable embodiment, the lithography composition is applied immediately above the substrate.

The application method is not particularly limited, and examples thereof include a method using a spinner or a coater. After application, the film according to the present invention is formed under reduced pressure and/or heating (soft-baking). The film can be formed by rotating the substrate at high speed and evaporating the solvent without heating. When the lithography composition according to the present invention is a resist composition, heating is performed, for example, using a hot plate. The heating temperature is preferably 80 to 250° C.; more preferably 80 to 200° C.; and further preferably 90 to 180° C. The heating time is preferably 30 to 600 seconds; more preferably 30 to 300 seconds; and further preferably 60 to 180 seconds. Heating is preferably carried out in an air or nitrogen gas atmosphere.

The film thickness of the resist film varies depending on the exposure wavelength, but is preferably 100 to 50,000 nm. When a KrF excimer laser is used for the exposure, the film thickness of the resist film is preferably 100 to 5,000 nm; more preferably 100 to 1,000 nm; and further preferably 400 to 800 nm.

When the lithography composition according to the present invention is a resist composition, the method for manufacturing a resist pattern according to the present invention comprises the following steps:
forming a film using the lithography composition by the above-described method;
(3) exposing the film with radiation; and
(4) developing the film to form a resist pattern.

Exposure is performed to the film formed using the resist composition, through a predetermined mask. The wavelength of the light to be used for the exposure is not particularly limited, but it is preferable to expose with light having a wavelength of 13.5 to 365 nm. In particular, i-line (wavelength: 365 nm), KrF excimer laser (wavelength: 248 nm), ArF excimer laser (wavelength: 193 nm), extreme ultraviolet ray (wavelength: 13.5 nm) and the like can be used, and preferred one is KrF excimer laser. These wavelengths allow a range of ±1%. After exposure, post exposure bake can be performed, as necessary. The post exposure baking temperature is preferably 80 to 150° C.; more preferably 100 to 140° C., and the heating time is 0.3 to 5 minutes; preferably 0.5 to 2 minutes.

The exposed film is developed using a developer. The developer to be used is preferably a tetramethylammonium hydroxide (TMAH) aqueous solution of 2.38 mass %. The temperature of the developer is preferably 5 to 50° C., more preferably 25 to 40° C., and the development time is preferably 10 to 300 seconds, more preferably 30 to 60 seconds.

Using such a developer, the film can be easily dissolved and removed at room temperature. Further, to these developers, for example, a surfactant can also be added.

When a negative type resist composition is used, the exposed region of the photoresist layer is removed by development to form a resist pattern. The resist pattern can be further made finer, for example, using a shrink material.

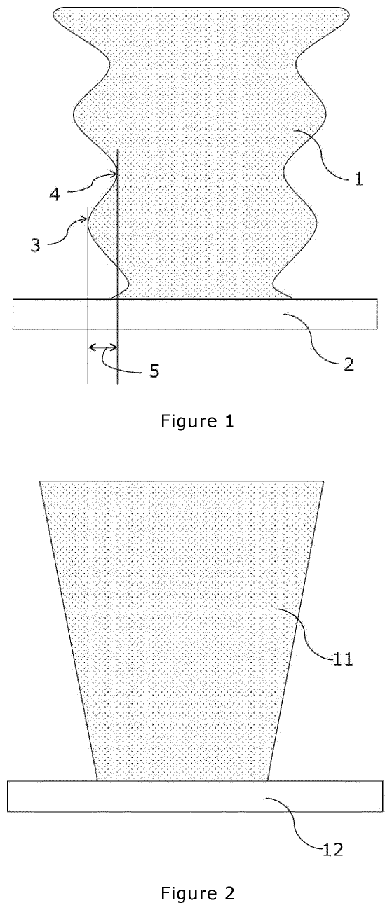

FIG. 1 is a schematic illustration showing the cross-sectional view of a negative type resist pattern when affected by standing wave. A resist pattern 1 is formed on a substrate 2. When a waveform having a large amplitude is formed in the cross section in this way, the resist top shape greatly fluctuates with a slight difference in film thickness, and the dimensional accuracy deteriorates, so that it is preferable that such an amplitude is smaller. Here, upward from the point where the substrate and the resist pattern are in contact with each other, the first point where the width of the resist pattern becomes maximum is set as the antinode 3, and the point immediately above it where the width of the resist pattern is the minimum is set as the node 4. Further, the distance between the antinode and the node in the direction parallel to the substrate is referred to as the internode distance 5. It is preferable that the internode distance is smaller, and particularly, the internode distance/desired pattern width (hereinafter sometimes referred to as the standing wave index) is preferably less than 10%; more preferably 5% or less; and further preferably 1% or less. Here, the desired pattern width may be the width of the top of the resist when it is assumed not to be affected by standing wave. By reducing standing wave that appears in the resist pattern, pattern collapse, which is caused due to undesired shape or formation of a notch, is suppressed and stable formation of a finer pattern is facilitated.

FIG. 2 is a schematic illustration showing the cross-sectional view of a negative type resist pattern when not affected by standing wave. In the negative resist, since the polymer is insolubilized through the acid generated by the exposure, it is difficult for light to reach the lower part and the acid is generated less than in the upper part, and the lower part is less insolubilized than the upper part. Therefore, the formed pattern tends to have a reverse tapered shape. In FIG. 2, neither antinode nor node exists, and in this case, the standing wave index is considered to be zero.

The method for manufacturing a metal pattern according to the present invention comprises the following steps:
forming a resist pattern by the above-described method;
(5a) forming a metal layer on the resist pattern; and
(6a) removing the remaining resist pattern and the metal layer thereon. Subsequent to the steps (1) to (4), the steps (5a) and (6a) are carried out. The order of the steps is as described above.

The metal layer is formed, for example, by vapor deposition or spattering of a metal such as gold or copper (which can be a metal oxide or the like). After that, the resist pattern can be formed by removing the resist pattern together with the metal layer formed on the upper part of the resist pattern, using a stripper. The stripper is not particularly limited as long as it is one used as a stripper for resist, and for example, N-methylpyrrolidone (NMP), acetone, or an alkaline solution is used. When the resist according to the present invention is a negative type one, it tends to have a reverse tapered shape as described above. When the resist according to the present invention is a negative type, it tends to have a reverse tapered shape as described above. In the case of the reverse tapered shape, between the metal on the resist pattern and the metal formed on the region where the resist pattern is not formed is distant, so that the former metal can be easily removed.

The method for manufacturing a pattern substrate according to the present invention comprises the following steps:
forming a resist pattern by the above-described method;
(5b) etching using the resist pattern as a mask; and
(6b) processing the substrate.
   The etching can be either dry etching or wet etching, and the etching can be performed a plurality of times. Subsequent to the steps (1) to (4), the steps (5b) and (6b) are carried out. The order of the processes is as described above.

The substrate can be etched directly using the resist pattern as a mask. An intervening layer such as BARC and planarity layer can be etched using the resist pattern as a mask to form a pattern of the intervening layer, and then the substrate can be etched using the pattern of the intervening layer as a mask.

In addition, the method for manufacturing a pattern substrate according to the preset invention comprises the following steps:
forming a resist pattern by the above-described method;
(5c) etching the resist pattern; and
(5d) etching the substrate.
   Subsequent to the steps (1) to (4), the steps (5c) and (5d) are carried out. The order of the steps is as described above.

Here, the combination of the steps (5c) and (5d) is repeated at least twice; and the substrate consists of a laminate of several Si-containing layers, in which at least one Si-containing layer is conductive and at least one Si-containing layer is electrically insulative. Preferably, the conductive Si-containing layers and electrically insulative Si-containing layers are alternately laminated. Here, the film thickness of the resist film formed from the lithography composition is preferably 0.5 to 200 μm.

After that, if necessary, the substrate is further processed to form a device. Known methods can be applied to this further processing. The method for manufacturing a device according to the present invention comprises either of the above-described method, and preferably, a step of forming a wiring on the processed substrate is further comprised. Examples of the device include a semiconductor device, a liquid crystal display device, an organic EL display device, a plasma display device, and a solar cell device. The device is preferably a semiconductor device.

### EXAMPLES

The present invention is explained below by use of the various examples. The embodiment of the present invention is not limited only to these examples.

The components used hereinafter are shown below.

The organic acid compound (AA) used are as follows.
AA1: (+)-10-Camphorsulfonic Acid (TCI)

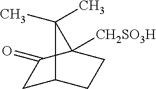

AA2: p-toluenesulfonic acid

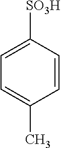

The basic compound (AB) used is as follows.
AB1: tris[2-(2-methoxyethoxy)ethyl]amine (TCI)

The solvent (B) used are as follows.
B1: PGMEA
B2: PGME

The film-forming component (C) used are as follows.
C1-1: CST 7030 random copolymer (p-hydroxystyrene (70), styrene (30)), Mw: about 9,700 (Maruzen Petrochemical)

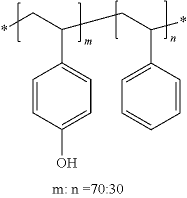

C1-2: VP-3500, p-hydroxystyrene, Mw: about 5,000 (Nippon Soda)

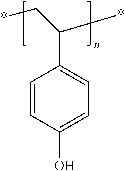

The acid generator (D) used is as follows.
D1: TPS-C₁ (Heraeus)

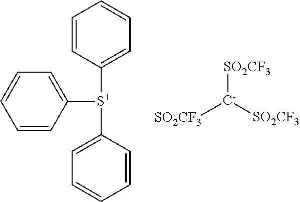

D2: TPS-SA (Toyo Gosei)

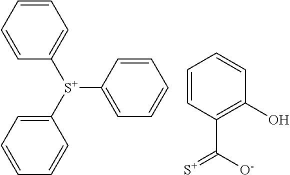

The cross-linking agent (E) used is as follows.
E1: DML-POP, Honshu Chemical Industry

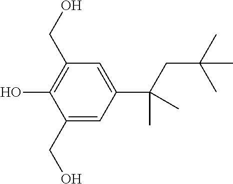 [SMILES: CC(C)(C)CC(C)(C)c1cc(CO)c(O)c(CO)c1]

The component (F) used is as follows.
F1: Megaface R2011, DIC

### Preparation of Example Composition 1

B1 (66.8 g) and B2 (16.7 g) are mixed to prepare a B1B2 mixed solvent. To this, 0.067 g of AA1 and 0.162 g of AB1 are added, and the mixture is stirred for 5 minutes. Then, 7.457 of C1-1, 6.883 g of C1-2, 0.580 g of D1, 1.337 g of E1 and 0.014 g of F1 are added to the mixture. The solution is mixed at room temperature and it is visually confirmed that the solid components dissolve. Example Composition 1 is obtained.

### Preparations of Example Compositions 2 to 5 and Comparative Example Composition 1

Example Compositions 2 to 5 and Comparative Example Composition 1 are prepared in the same manner as in the preparation example of Example Composition 1 except that the components are changed as shown in Table 1.

TABLE 1
Each addition amount in the total mass 100 g

| | | | | | | | Comparative |
|---|---|---|---|---|---|---|---|
| | | | | | | | Example |
| | | Example Composition | | | | | Composition |
| | | 1 | 2 | 3 | 4 | 5 | 1 |
| Component (AA) | AA1 | 0.067 | 0.099 | 0.132 | — | 0.262 | — |
| (g) | AA2 | — | — | — | 0.082 | — | — |
| Component (AB) | AB1 | 0.162 | 0.208 | 0.253 | 0.208 | — | 0.070 |
| (g) | | | | | | | |
| Component (B) | B1 | 66.8 | 66.8 | 66.8 | 66.8 | 66.8 | 66.8 |
| (g) | B2 | 16.7 | 16.7 | 16.7 | 16.7 | 16.7 | 16.7 |
| Component (C) | C1-1 | 7.457 | 7.421 | 7.385 | 7.428 | 7.327 | 7.529 |
| (g) | C1-2 | 6.883 | 6.850 | 6.817 | 6.857 | 6.763 | 6.950 |
| Component (D) | D1 | 0.580 | 0.578 | 0.575 | 0.578 | 0.570 | 0.586 |
| (g) | D2 | — | — | — | — | 0.251 | — |
| Component (E) | E1 | 1.337 | 1.330 | 1.324 | 1.332 | 1.314 | 1.350 |
| (g) | | | | | | | |
| Component (F) | F1 | 0.014 | 0.014 | 0.014 | 0.014 | 0.014 | 0.014 |
| (g) | | | | | | | |

### Resist Pattern Forming Example

A BARC having a film thickness of 45 nm is formed by subjecting AZ KrF-17B (Merck Electronics, hereinafter referred to as ME) to spin coating on the surface of a silicon substrate (SUMCO, 8 inches) and soft baking at 180° C. for 60 seconds. On it, a resist film having a film thickness of 780 nm is formed by subjecting each above prepared composition to spin coating and soft baking at 110° C. for 60 seconds. In accordance with this configuration, the light reflectance of the KrF (248 nm) is set to become 7%. The obtained substrate is exposed with KrF using an exposure apparatus (Canon, FPA-3000EX5). As the exposure mask, a mask having a line:space=1:1 and spaces of 300 nm continuing multiple times, which are gradually decreasing as shown below is used:
300 nm, 280 nm, 260 nm, 240 nm, 220 nm, 200 nm, 190 nm, 180 nm, 170 nm, 160 nm, 150 nm, 140 nm, 130 nm, 120 nm, 110 nm, 100 nm.

The substrate is subjected to post-exposure baking (PEB) at 100° C. for 60 seconds. Then, the resist film is subjected to paddle development for 60 seconds with a 2.38% TMAH aqueous solution. In the state that the paddle developer is paddled on the substrate, pure water is started to be flown onto the substrate, the paddle developer is replaced with pure water while rotating, and spin drying is performed at 2,000 rpm.

### Standing Wave Reduction Evaluation

The reduction of standing wave is evaluated. The pattern in which the space of the resist pattern formed in the above Resist Pattern Forming Example corresponds to 300 nm is observed. A cut piece is prepared from the substrate and observed by SEM (SU8230, Hitachi High-Technologies). The internode distance defined above is measured (Offline CD Measurement Software Version 6.00, Hitachi High-Technologies). The standing wave index is calculated by dividing the internode distance by the desired pattern width. Evaluation is performed according to the following evaluation criteria.
A: Standing wave index is less than 1%.
B: Standing wave index is more than 1% and less than 5%.
C: Standing wave index is 5% or more.

### Minimum Size Evaluation

The minimum size of the resist pattern formed in the above Resist Pattern Forming Example is evaluated. It is checked if any pattern collapse is not occurred starting from the large pattern, and the observation target is gradually transferred to the smaller pattern. The pattern immediately before the pattern collapse can be confirmed (the pattern that has not been collapsed) is taken the minimum size.

### Exposure Latitude Evaluation

Except for the following, the same operation as in the “Resist Pattern Forming Example” is carried out. First, the exposure amount at which the dimension of the resist pattern is 300 nm in a region having line:space=1:1 and spaces of 300 nm continuing multiple times is defined as optimal exposure amount (Eop). Then, substrates are prepared in the same manner as described above, and the exposure amount is changed so that the dimension of the resist pattern becomes 300 nm±30 nm. A range of the exposure amount in which the dimension becomes 300 nm±30 nm is defined as (Emax−Emin).

((Emax−Emin)/Eop) is defined as the exposure latitude. When this value is 10% or more, it is evaluated as A, 5% or more and less than 10% as B, and less than 5% as C.

### Depth of Focus Evaluation

Except for the following, the same operation as in the “Resist Pattern Forming Example” is carried out. A focus position of the exposure machine where the dimension of a resist pattern in a region having line:space=1:1 and spaces of 300 nm continuing multiple times is defined as optimum focus value (Best Focus). As the exposure amount at this time, the above-described optimal exposure amount (Eop) of “Exposure Latitude Evaluation” is used. Then, substrates are prepared in the same manner as described above, and the focus position of the exposure machine is changed so that the dimension of the resist pattern corresponding to 300 nm becomes 300 nm±30 nm. When the focus position of the exposure machine is shifted from the optimum value, the width of the depth of focus at which the dimension of resist pattern becomes 300 nm±30% of 1.2 μm or more is evaluated as A, 0.8 μm or more and less than 1.2 μm as B, and less than 0.8 μm as C.

### Removability Evaluation

Resist patterns are obtained by carrying out the same operation as in the “Resist Pattern Forming Example”. AZ 400T Stripper (ME) at 60° C. is used as a stripper. The substrate is immersed in the stripper for 15 minutes while maintaining the temperature of the stripper at 60° C. This is spin-dried at 1,000 rpm. A resist pattern of 300 nm size in a region having line:space=1:1 and spaces of 300 nm continuing multiple times is observed by SEM (SU8230, Hitachi High-Technologies) at 50,000 times magnification. Those can be cleanly removed are evaluated as A, those in which residues are confirmed are evaluated as B, and those in which the resist pattern remains on the substrate as it is are evaluated as C.

TABLE 2
Evaluation Results

| | | | | | | Comparative |
|---|---|---|---|---|---|---|
| | | | | | | Example |
| | Example Composition | | | | | Composition |
| | 1 | 2 | 3 | 4 | 5 | 1 |
| Standing Wave Reduction | B | A | A | A | A | C |
| Minimum Size (nm) | 220 | 200 | 220 | 220 | 200 | 260 |
| Exposure latitute | A | A | A | B | A | A |
| Depth Of Focus | A | A | A | A | B | A |
| Removability | A | A | A | A | A | A |

### EXPLANATION OF SYMBOLS

1. substrate
2. resist pattern affected by standing wave
3. antinode
4. node
5. internode distance
11. substrate
12. resist pattern not affected by standing wave.

1.-15. (canceled)

16. A method for using a composition comprising an organic acid compound (AA) to reduce standing wave in a lithography process, wherein the organic acid compound (AA) is represented by the formula (aa): 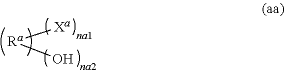
where
R^{a} is C₁₋₄₀ hydrocarbon group, where at least one methylene in the hydrocarbon group can be replaced with carbonyl,
X^{a} is SO₃H or COOH,
na1 is 1 or 2, and
na2 is 0, 1 or 2.

17. The method according to claim 16, wherein the composition is applied above a substrate to form a film.

18. The method according to claim 16, wherein the composition further comprises a solvent (B).

19. A lithography composition comprising an organic acid compound (AA) and a solvent (B), wherein the organic acid compound (AA) is represented by the formula (aa): 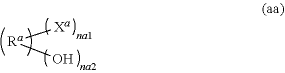
where
R^{a} is C₁₋₄₀ hydrocarbon group, where at least one methylene in the hydrocarbon group can be replaced with carbonyl,
X^{a} is SO₃H or COOH,
na1 is 1 or 2, and
na2 is 0, 1 or 2.

20. The lithography composition according to claim 19, wherein the organic acid compound (AA) is represented by the formula (aa-1), (aa-2), (aa-3) or (aa-4): 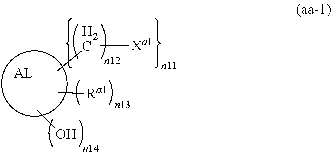
where
AL is a C₅₋₂₀ alicyclic ring, where at least one methylene in the alicyclic ring is optionally replaced with carbonyl,
X^{a1} is SO₃H or COOH,
R^{a1} is each independently C₁₋₅ alkyl,
n11 is 1 or 2,
n12 is 0, 1 or 2,
n13 is 0, 1, or 2, and
n14 is 0, 1 or 2; 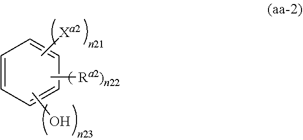
where
X^{a2} is SO₃H or COOH,
R^{a2} is each independently C₁₋₁₅ alkyl,
n21 is 1 or 2,
n22 is 0, 1 or 2, and
n23 is 0, 1 or 2;
R^{a3}—X^{a3} (aa-3)
where
X^{a3} is SO₃H or COOH, and
R^{a3} is C₁₋₁₀ alkyl, C₁₋₁₀ fluorine-substituted alkyl or C₂₋₁₀ alkenyl;
X^{a4}—R^{a4}—X^{a4} (aa-4)
where
X^{a4} is SO₃H or COOH, and
R^{a3} is C₁₋₁₀ alkylene or C₂₋₁₀ alkenylene.

21. The lithography composition according to claim 19, further comprising a film-forming component (C).

22. The lithography composition according to claim 19, further comprising an additive (G).

23. The lithography composition according to claim 19, wherein the content of the organic acid compound (AA) is 0.001 to 10 mass %, based on the solvent (B).

24. The lithography composition according to claim 19, which is a lithography film-forming composition.

25. A method for manufacturing a film comprising the following steps:
(1) applying the lithography composition according to claim 19 above a substrate; and
(2) forming a film from the lithography composition under reduced pressure and/or heating.

26. A method for manufacturing a resist pattern comprising the following steps:
forming a film from the lithography composition by the method according to claim 25;
(3) exposing the film with radiation; and
(4) developing the film to form a resist pattern,
wherein the lithography composition is a resist composition.

27. A method for manufacturing a metal pattern comprising the following steps:
forming a resist pattern by the method according to claim 26;
(5a) forming a metal layer on the resist pattern; and
(6a) removing the remaining resist pattern and the metal layer thereon.

28. A method for manufacturing a pattern substrate comprising the following steps:
forming a resist pattern by the method according to claim 26;
(5b) etching using the resist pattern as a mask; and
(6b) processing the substrate.

29. A method for manufacturing a pattern substrate comprising the following steps:
forming a resist pattern by the method according to claim 26;
(5c) etching the resist pattern; and
(5d) etching the substrate,
wherein the combination of the steps (5c) and (5d) is repeated at least twice; and
the substrate consists of a laminate of several Si-containing layers, in which at least one Si-containing layer is conductive and at least one Si-containing layer is electrically insulative.

30. A method for manufacturing a device comprising the method according to claim 25.
